(19) United States
(12) Patent Application Publication
(10) Pub. No.: US 2017/0263421 A1
(43) Pub. Date: Sep. 14, 2017

(54) Plasma Processing Apparatus and Plasma Processing Method

(71) Applicant: TOKYO ELECTRON LIMITED, Tokyo (JP)

(72) Inventors: Taro IKEDA, Nirasaki City (JP); Shigeru KASAI, Nirasaki City (JP)

(21) Appl. No.: 15/455,566

(22) Filed: Mar. 10, 2017

(30) Foreign Application Priority Data
Mar. 14, 2016 (JP) 2016-049067

(51) Int. Cl. H01J 37/32

(52) U.S. Cl. CPC H01J 37/32266; H01J 37/32715; H01J 37/3222; H01J 37/32467; H01J 2237/332; H01J 2237/334

(57) ABSTRACT

There is provided a plasma processing apparatus including a microwave introduction part configured to radiate microwaves transmitted by a microwave transmission part inside a process container. The microwave introduction part includes a conductive member constituting a ceiling portion of the process container and having a recess formed to face the mounting surface, a plurality of slots forming a part of the conductive member and configured to radiate the microwaves transmitted via the microwave transmission part, and a microwave transmitting member fitted to the recess of the conductive member and configured to transmit and introduce the microwaves radiated from the plurality of slots into the process container. The microwave transmitting member is provided to be shared with the microwaves transmitted via transmission paths and includes an interference suppressing part configured to suppress interference of the microwaves in the microwave transmitting member.

### CROSS-REFERENCE TO RELATED APPLICATION

This application claims the benefit of Japanese Patent Application No. 2016-049067, filed on Mar. 14, 2016, in the Japan Patent Office, the disclosure of which is incorporated herein in its entirety by reference.

### TECHNICAL FIELD

The present disclosure relates to a plasma processing apparatus and a plasma processing method for processing a workpiece with microwave plasma.

### BACKGROUND

In the course of manufacturing a semiconductor device, for example, a film forming process such as an oxidizing process, a nitriding process or the like, an etching process, and the like are performed with respect to a workpiece such as a semiconductor wafer or the like through the use of plasma. Recently, there is an increasing demand for coping with miniaturization in an effort to develop a device for the next and subsequent generation. In the meantime, from the viewpoint of enhancing production efficiency, the size of a workpiece is growing larger.

As the related art regarding a plasma process, there has been proposed a plasma processing apparatus which includes a plurality of microwave introduction mechanisms configured to introduce microwaves into a process container, a plurality of slots circumferentially disposed in a ceiling portion of the process container, and an annular microwave transmitting member configured to transmit microwaves radiated from the respective slots. In this plasma processing apparatus, the uniform spreading of plasma in the circumferential direction can be secured by the annular microwave transmitting member.

Furthermore, there has been proposed a plasma processing apparatus in which a choke groove for suppressing microwave propagation is formed around a microwave introduction opening in order to suppress excessive propagation of microwaves in a process container.

In order for a plasma processing apparatus to cope with the enlargement of a workpiece without unnecessarily increasing the number of microwave introduction parts, as in the apparatuses of the related art, it is effective to introduce microwaves from a plurality of microwave introduction mechanisms via one common microwave transmitting member. However, if the phases of the microwaves introduced from the plurality of microwave introduction mechanisms are different, microwave interference occurs inside the microwave transmitting member. Thus, there may be a case where the electric field intensity is biased and the uniformity of plasma is impaired.

### SUMMARY

Some embodiments of the present disclosure provide a plasma processing apparatus and a plasma processing method for introducing microwaves into a process container via one common microwave transmitting member, which are capable of effectively suppressing interference of microwaves inside the microwave transmitting member.

According to one embodiment of the present disclosure, there is provided a plasma processing apparatus including a process container configured to accommodate a workpiece, a mounting table disposed inside the process container and provided with a mounting surface configured to support the workpiece, a microwave output part configured to generate microwaves and to distribute and output the microwaves to a plurality of paths, a microwave transmission part configured to transmit the microwaves outputted from the microwave output part into the process container via a plurality of transmission paths, and a microwave introduction part configured to radiate the microwaves transmitted by the microwave transmission part inside the process container. The microwave transmission part includes tuner parts disposed in the respective transmission paths and configured to match impedance between the microwave output part and an interior of the process container. The microwave introduction part includes a conductive member constituting a ceiling portion of the process container and having a recess formed to face the mounting surface, a plurality of slots forming a part of the conductive member and configured to radiate the microwaves transmitted via the microwave transmission part, and a microwave transmitting member fitted to the recess of the conductive member and configured to transmit and introduce the microwaves radiated from the plurality of slots into the process container. The microwave transmitting member is provided to be shared with the microwaves transmitted via the transmission paths and includes an interference suppressing part configured to suppress interference of the microwaves in the microwave transmitting member.

According to another embodiment of the present disclosure, there is provided a plasma processing method for processing a workpiece using the aforementioned plasma processing apparatus.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory view schematically showing the schematic configuration of a plasma processing apparatus according to one embodiment of the present disclosure.

FIG. 2 is an explanatory diagram showing the configuration of a control part shown in FIG. 1.

FIG. 3 is an explanatory diagram showing the configuration of a microwave introduction device shown in FIG. 1.

FIG. 4 is a sectional view showing the configurations of a tuner part and a microwave introduction part.

FIG. 5 is a plan view showing the configuration of an upper portion of the microwave introduction part.

FIG. 6 is a plan view showing the configuration of a lower portion of the microwave introduction part.

FIG. 7 is a perspective view showing an external appearance of a microwave transmitting member.

FIG. 8 is an enlarged perspective view of a main portion of the microwave transmitting member showing a wall portion.

FIG. 9 is a diagram showing simulation results.

### DETAILED DESCRIPTION

Hereinafter, an embodiment of the present disclosure will be appropriately described in detail with reference to the drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Configuration Example of Plasma Processing Apparatus]

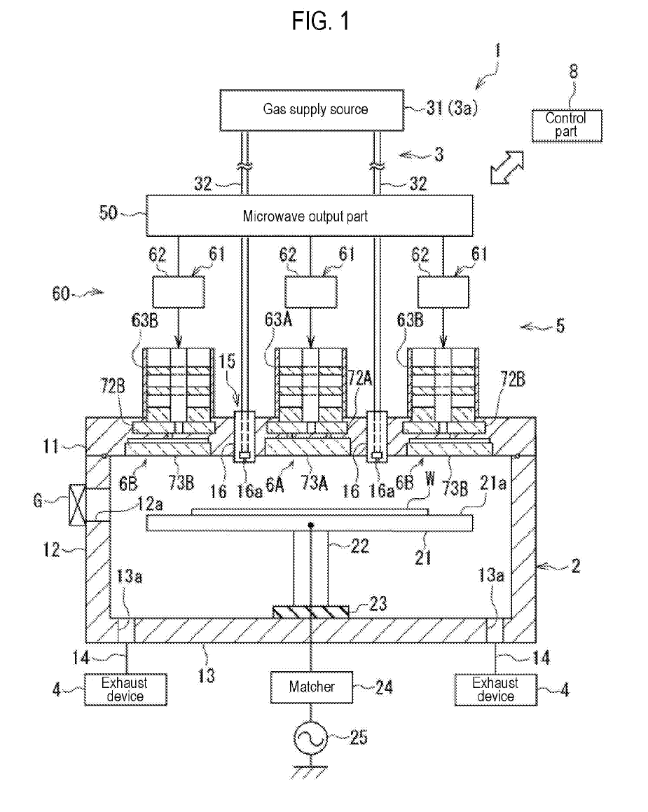

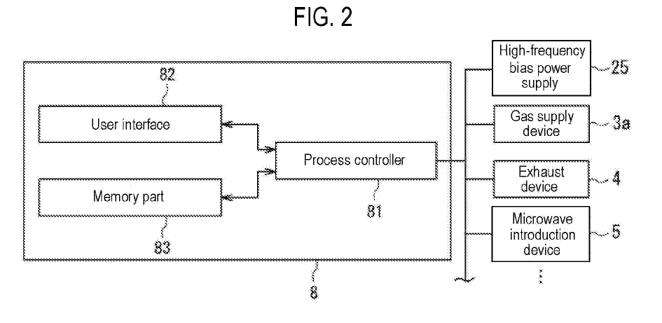

First, a plasma processing apparatus according to one embodiment of the present disclosure will be described. FIG. 1 is a sectional view schematically showing the schematic configuration of the plasma processing apparatus. FIG. 2 is an explanatory diagram showing the configuration of a control part shown in FIG. 1. The plasma processing apparatus 1 of the present embodiment is an apparatus that performs plasma processing upon a semiconductor wafer (hereinafter simply referred to as “wafer”) W through a plurality of successive operations. In this regard, examples of the plasma processing may include a film forming process such as a plasma oxidizing process, a plasma nitriding process or the like, a plasma etching process, and the like.

The plasma processing apparatus 1 includes a process container 2 configured to accommodate a wafer W as a workpiece, a mounting table 21 disposed inside the process container 2 and having a mounting surface 21a on which the wafer W is mounted, a gas supply mechanism 3 configured to supply a gas into the process container 2, an exhaust device 4 configured to depressurize and exhaust the interior of the process container 2, a microwave introduction device 5 configured to generate microwaves for generating plasma inside the process container 2 and to introduce the microwaves into the process container 2, microwave introduction parts 6A and 6B configured to radiate the microwaves from the microwave introduction device 5 into the process container 2, and a control part 8 configured to control the respective configuring parts of the plasma processing apparatus 1. Instead of the gas supply mechanism 3, an external gas supply mechanism not included in the configuration of the plasma processing apparatus 1 may be used as a part for supplying a gas into the process container 2.

### <Process Container>

The process container 2 has, for example, a substantially cylindrical shape. The process container 2 is made of, for example, a metallic material such as aluminum and its alloy. The microwave introduction device 5 is installed above the process container 2 and functions as a plasma generation part configured to generate plasma by introducing electromagnetic waves (microwaves) into the process container 2. The configuration of the microwave introduction device 5 will be described later in detail.

The process container 2 includes a plate-like ceiling portion 11, a bottom portion 13, and a sidewall portion 12 configured to connect the ceiling portion 11 and the bottom portion 13. The ceiling portion 11 has a plurality of recesses and functions as a conductive member constituting the microwave introduction parts 6A and 6B. The sidewall portion 12 has a loading/unloading gate 12a through which the wafer W is loaded and unloaded between the process container 2 and a transfer chamber (not shown) adjacent to the process container 2. A gate valve G is disposed between the process container 2 and the transfer chamber (not shown). The gate valve G has a function of opening and closing the loading/unloading gate 12a. The gate valve G hermetically seals the process container 2 in a closed state and allows the wafer W to transfer between the process container 2 and the transfer chamber (not shown) in an open state.

The bottom portion 13 has a plurality of (two, in FIG. 1) exhaust ports 13a. The plasma processing apparatus 1 further includes an exhaust pipe 14 that connects the exhaust ports 13a and the exhaust device 4. The exhaust device 4 includes an APC valve and a high-speed vacuum pump capable of depressurizing the internal space of the process container 2 at a high speed to a predetermined degree of vacuum. Examples of such a high-speed vacuum pump may include a turbo molecular pump and the like. By operating the high-speed vacuum pump of the exhaust device 4, the internal space of the process container 2 is depressurized to a predetermined degree of vacuum, for example, 0.133 Pa.

### <Mounting Table>

The mounting table 21 is configured to horizontally support a wafer W as a workpiece. The plasma processing apparatus 1 further includes a support member 22 configured to support the mounting table 21 in the process container 2 and an insulating member 23 made of an insulating material and provided between the support member 22 and the bottom portion 13 of the process container 2. The support member 22 has a cylindrical shape extending from the center of the bottom portion 13 toward the internal space of the process container 2. The mounting table 21 and the support member 22 are made of, for example, AlN or the like.

The plasma processing apparatus 1 further includes a high-frequency bias power supply 25 configured to supply high frequency power to the mounting table 21 and a matcher 24 provided between the mounting table 21 and the high-frequency bias power supply 25. The high-frequency bias power supply 25 supplies high frequency power to the mounting table 21 in order to draw ions into the wafer W.

Although not shown in the drawings, the plasma processing apparatus 1 further includes a temperature control mechanism configured to heat or cool the mounting table 21. For example, the temperature control mechanism controls the temperature of the wafer W within a range of 20 degrees C. (room temperature) to 900 degrees C. Furthermore, the mounting table 21 includes a plurality of support pins provided to be protrudable with respect to the mounting surface 21a. The support pins are vertically displaced by an arbitrary elevator mechanism so that the wafer W can be delivered to and from the transfer chamber (not shown) when the support pins are in a raised position.

The plasma processing apparatus 1 further includes a gas introduction part 15 provided in the ceiling portion 11 of the process container 2. The gas introduction part 15 includes a plurality of nozzles 16 having a cylindrical shape. Each of the nozzles 16 has a gas hole 16a formed on its lower surface.

### <Gas Supply Mechanism>

The gas supply mechanism 3 includes a gas supply device 3a including a gas supply source 31, and a pipe 32 configured to connect the gas supply source 31 and the gas introduction part 15. Although FIG. 1 shows a single gas supply source 31, the gas supply device 3a may include a plurality of gas supply sources depending on the type of gases to be used.

The gas supply source 31 is used, for example, as a gas supply source of a rare gas for plasma generation or a gas supply source of a process gas used for an oxidizing process, a nitriding process, an etching process or the like. There may be a case where a rare gas is used together with a process gas for an oxidizing process, a nitriding process, an etching process or the like.

Although not shown in the drawings, the gas supply device 3a further includes a mass flow controller and an opening/closing valve provided in the middle of the pipe 32. The type of gases to be supplied into the process container 2, the flow rate of these gases, and the like are controlled by the mass flow controller and the opening/closing valve.

### <Control Part>

The respective components of the plasma processing apparatus 1 are connected to the control part 8 and controlled by the control part 8. The control part 8 is typically a computer. In the example shown in FIG. 2, the control part 8 includes a process controller 81 provided with a CPU, and a user interface 82 and a memory part 83, which are connected to the process controller 81.

In the plasma processing apparatus 1, the process controller 81 is a control part for generally controlling the respective components (for example, the high-frequency bias power supply 25, the gas supply device 3a, the exhaust device 4, the microwave introduction device 5, etc.) related to process conditions such as, for example, a temperature, a pressure, a gas flow rate, high frequency power for bias application, a microwave output, and the like.

The user interface 82 includes a keyboard or a touch panel through which a process manager performs an input manipulation of commands in order to manage the plasma processing apparatus 1, a display configured to visually display the operating status of the plasma processing apparatus 1, and the like.

The memory part 83 stores a control program (software) for realizing various processes executed by the plasma processing apparatus 1 under the control of the process controller 81, a recipe in which process condition data and the like are recorded, and the like. The process controller 81 calls an arbitrary control program or recipe from the memory part 83 and executes the same according to necessity such as an instruction from the user interface 82. As a result, under the control of the process controller 81, a desired process is performed in the process container 2 of the plasma processing apparatus 1.

The control program and recipe may be used in a state stored in a computer-readable storage medium such as a CD-ROM, a hard disk, a flexible disk, a flash memory, a DVD, a Blu-ray disk, or the like. In addition, it may be possible to use the recipe on-line by frequent transmission from other devices via, for example, a dedicated line.

### <Microwave Introduction Device and Microwave Introduction Part>

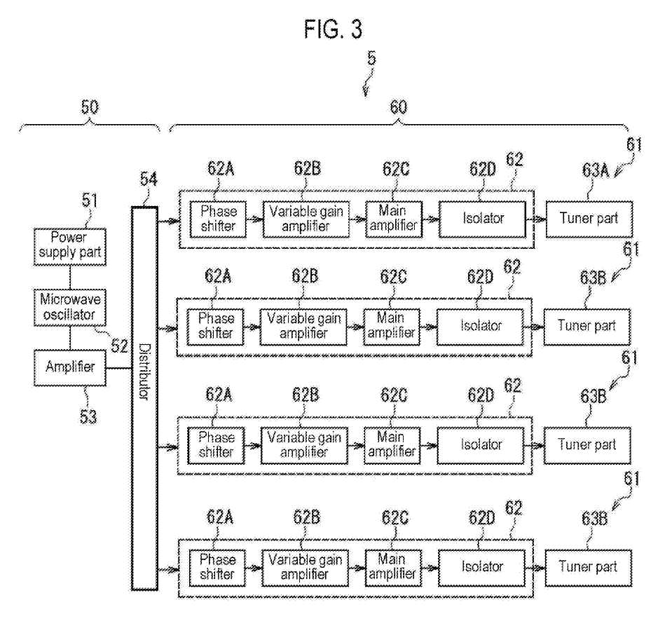

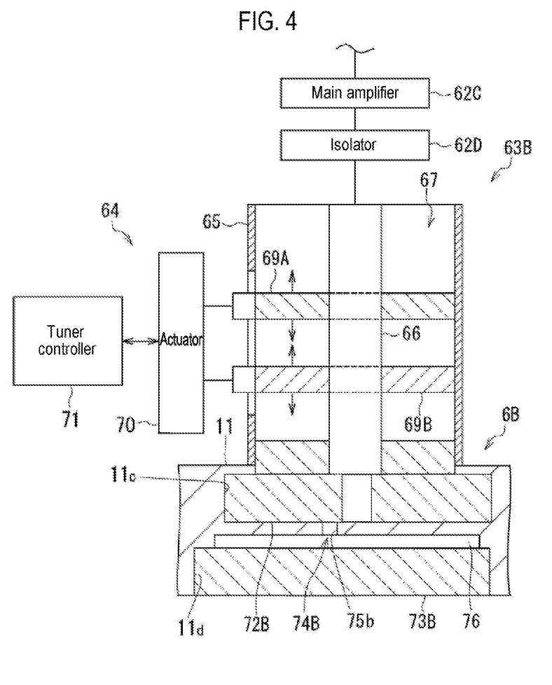

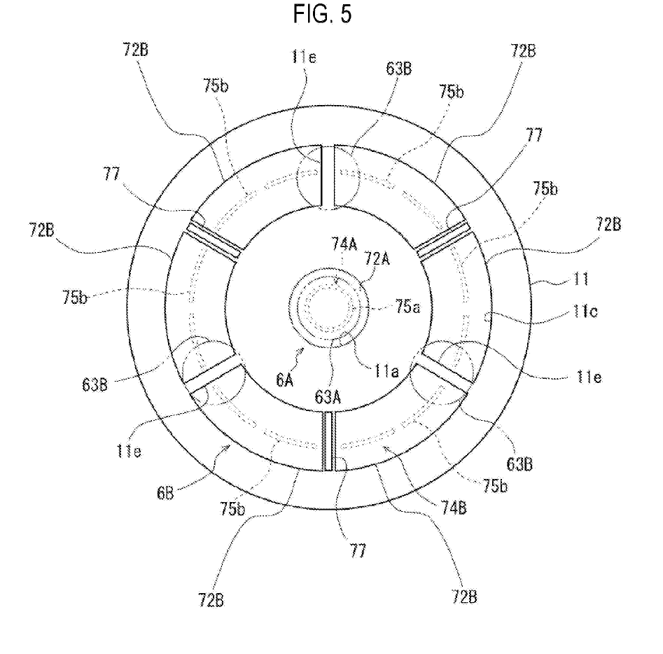

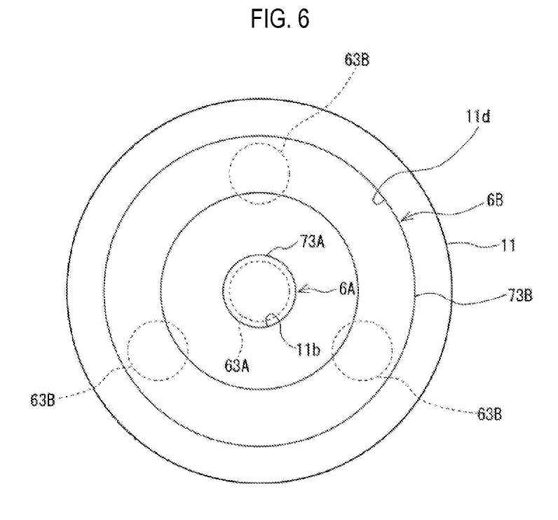

Next, the configurations of the microwave introduction device 5 and the microwave introduction parts 6A and 6B will be described in detail with reference to FIG. 1 and FIGS. 3 to 6. FIG. 3 is an explanatory diagram showing the configuration of the microwave introduction device 5. FIG. 4 is a sectional view showing the configurations of the tuner part 63B and the microwave introduction part 6B which form a part of the microwave introduction device 5. FIG. 5 is a plane view showing the configurations of the microwave introduction parts 6A and 6B as viewed from above the ceiling portion 11. FIG. 6 is a plane view showing the configurations of the microwave introduction parts 6A and 6B as viewed from below the ceiling portion 11.

### <Microwave Introduction Device>

As described above, the microwave introduction device 5 is provided above the process container 2 and functions as a plasma generation part configured to generate plasma by introducing electromagnetic waves (microwaves) into the process container 2. As shown in FIGS. 1 and 3, the microwave introduction device 5 includes a microwave output part 50 configured to generate microwaves and to distribute and output the microwaves to a plurality of paths, and a microwave transmission part 60 configured to transmit the microwaves outputted from the microwave output part 50 to the process container 2.

### (Microwave Output Part)

The microwave output part 50 includes a power supply part 51, a microwave oscillator 52, an amplifier 53 configured to amplify microwaves oscillated by the microwave oscillator 52, and a distributor 54 configured to distribute the microwaves amplified by the amplifier 53 to a plurality of paths. The microwave oscillator 52 oscillates microwaves (for example, PLL-oscillation) at a predetermined frequency (for example, 860 MHz). The frequency of the microwaves is not limited to 860 MHz but may be 2.45 GHz, 8.35 GHz, 5.8 GHz, 1.98 GHz, or the like. The distributor 54 distributes the microwaves while matching the impedances on the input side and the output side.

### (Microwave Transmission Part)

The microwave transmission part 60 includes a plurality of antenna modules 61. The antenna modules 61 are respectively configured to introduce the microwaves distributed by the distributor 54 into the process container 2. Each of the antenna modules 61 includes an amplifier part 62 configured to mainly amplify and output the distributed microwaves and a tuner part 63A or 63B configured to adjust the impedance of the microwaves outputted from the amplifier part 62.

In the present embodiment, all the amplifier parts 62 of the antenna modules 61 have the same configuration. The amplifier part 62 includes a phase shifter 62A serving as a phase adjusting part to change the phase of the microwaves, a variable gain amplifier 62B configured to adjust the power level of the microwaves inputted to a main amplifier 62C, a main amplifier 62C configured as a solid state amplifier, and an isolator 62D configured to isolate reflected microwaves which are reflected by a slot antenna portion of the microwave introduction part 6A or 6B to be described later and are moved toward the main amplifier 62C.

As shown in FIG. 1, the tuner parts 63A and 63B are provided in the ceiling portion 11. In the present embodiment, the tuner part 63A is provided in the central region of the ceiling portion 11 and three tuner parts 63B (only two of which are shown in FIG. 1) are provided in the peripheral region of the ceiling portion 11. The three tuner parts 63B are equally arranged at an angle of 120 degrees in the circumferential direction so as to surround the tuner part 63. FIG. 4 representatively shows the configuration of one tuner part 63B disposed in the upper portion of the peripheral region of the ceiling portion 11. The tuner part 63A disposed in the upper portion of the central region of the ceiling portion 11 has the same configuration.

Each of the tuner parts 63A and 63B includes a slug tuner 64 configured to match the impedance, a main body container 65 made of a metallic material and having a cylindrical shape extending in the vertical direction in FIG. 4, and an inner conductor 66 extending in the same direction as the direction that the main body container 65 extends within the main body container 65. The main body container 65 and the inner conductor 66 constitute a coaxial tube. The main body container 65 constitutes an outer conductor of the coaxial tube. The inner conductor 66 has a rod-like shape or a tubular shape. A space between the inner circumferential surface of the main body container 65 and the outer circumferential surface of the inner conductor 66 forms a microwave transmission path 67.

As shown in FIG. 4, the slug tuner 64 includes two slugs 69A and 69B arranged in the base end side (upper end side) portion of the main body container 65, an actuator 70 configured to actuate the two slugs 69A and 69B, and a tuner controller 71 configured to control the actuator 70.

The slugs 69A and 69B have a plate-like annular shape and are disposed between the inner circumferential surface of the main body container 65 and the outer circumferential surface of the inner conductor 66. Furthermore, the slugs 69A and 69B are made of a dielectric material. As the dielectric material for forming the slugs 69A and 69B, it may be possible to use, for example, high-purity alumina having a relative dielectric constant of 10.

The slug tuner 64 moves the slugs 69A and 69B in the vertical direction using the actuator 70 based on a command from the tuner controller 71. As a result, the slug tuner 64 adjusts the impedance. For example, the tuner controller 71 adjusts the positions of the slugs 69A and 69B so that the impedance of a terminal portion becomes 50Ω.

In the present embodiment, the main amplifier 62C, the slug tuner 64 and the slot antenna portion 74A or 74B (to be described later) of the microwave introduction part 6A or 6B are arranged close to each other. In particular, the slug tuner 64 and the slot antenna portion 74A or 74B constitute a lumped constant circuit and further function as a resonator. The impedance mismatch can be highly accurately resolved up to the slot antenna portion 74A or 74B by the slug tuner 64, so that the substantially mismatched part can be used as a plasma space. As a result, plasma can be highly accurately controlled by the slug tuner 64.

In the tuner parts 63A and 63B configured as described above, the microwaves amplified by the main amplifier 62C are transmitted to the microwave introduction parts 6A and 6B through a space between the inner circumferential surface of the main body container 65 and the outer circumferential surface of the inner conductor 66 (the microwave transmission path 67).

### <Microwave Introduction Part>

The microwave introduction parts 6A and 6B are provided in the ceiling portion 11. In the present embodiment, the microwave introduction parts 6A and 6B include a microwave introduction part 6A provided in the central region of the ceiling portion 11 and a microwave introduction part 6B provided in the peripheral region of the ceiling portion 11. The microwave introduction part 6A includes a part of the ceiling portion 11, a microwave retardation member 72A, a slot antenna portion 74A, and a microwave transmitting member 73A. The microwave introduction part 6B includes a part of the ceiling portion 11, microwave retardation members 72B, a slot antenna portion 74B, and a microwave transmitting member 73B. The microwave introduction part 6A and the microwave introduction part 6B slightly differ in configuration from each other as described below.

### (Microwave Introduction Part in Central Region)

As shown in FIG. 5, at the upper portion of the central region of the ceiling portion 11, a recess 11a is formed in a region vertically overlapping with the arrangement region of the tuner part 63A. A disc-shaped microwave retardation member 72A is fitted to the recess 11a. As shown in FIG. 6, on the lower surface of the central region of the ceiling portion 11, a recess 11b is formed in a region vertically overlapping the microwave retardation member 72A. A disc-shaped microwave transmitting member 73A is fitted to the recess 11b. A slot antenna portion 74A is formed between the lower portion of the microwave retardation member 72A and the microwave transmitting member 73A. A slot 75a is formed in the slot antenna portion 74A.

The slot antenna portion 74A mode-converts the microwaves transmitted from the tuner part 63A as TEM waves into TE waves using the slot 75a and radiates the microwaves into the process container 2 via the microwave transmitting member 73A. The shape and size of the slot 75a are appropriately adjusted so that the uniform electric field intensity can be obtained without causing mode jump. For example, the slot 75a is formed in an annular shape as shown in FIG. 5. As a result, no joint exists in the slot 75a, a uniform electric field can be formed, and mode jump is hard to occur.

### (Microwave Introduction Part in Peripheral Region)

As shown in FIGS. 4 and 5, on the upper portion of the peripheral region of the ceiling portion 11, a recess 11c is formed along an annular region vertically overlapping with the arrangement region of the tuner part 63B, and a plurality of microwave retardation members 72B is fitted to the recess 11c. As shown in FIGS. 4 and 6, on the lower surface of the peripheral region of the ceiling portion 11, a recess 11d is formed in an annular region vertically overlapping with the arrangement region of the tuner part 63B, and a microwave transmitting member 73B is fitted to the recess 11d. As shown in FIG. 4, a slot antenna portion 74B and a plurality of dielectric layers 76 are formed between the microwave retardation members 72B and the microwave transmitting member 73B.

As shown in FIG. 5, each of the microwave retardation members 72B has an arcuate shape and the plurality of the microwave retardation members 72B is arranged so as to form an annular shape. The number of the microwave retardation members 72B is twice as many as the number of the tuner parts 63B. For example, six microwave retardation members 72B are provided in the present embodiment. These microwave retardation members 72B are provided at equal intervals. The adjacent microwave retardation members 72B are separated by a partition portion 11e forming a part of the ceiling portion 11, which is a conductive member, or by a wall portion 77 forming a part of the microwave transmitting member 73B, which will be described later. For example, in the region vertically overlapping with the three tuner parts 63B, the partition portion 11e is inserted between the adjacent microwave retardation members 72B from the lower side, whereby the adjacent microwave retardation members 72B are separated from each other. On the other hand, in the remaining three places not vertically overlapping with the tuner parts 63B, the wall portion 77 of the microwave transmitting member 73B is inserted between the adjacent microwave retardation members 72B from the lower side, whereby the adjacent microwave retardation members 72B are separated from each other. It is preferred that the wall portion 77 and the microwave retardation members 72B existing on both sides of the wall portion 77 are spaced apart from each other with a clearance of, for example, about 2 to 3 mm, left therebetween.

As shown in FIG. 5, the tuner parts 63B are disposed above the two microwave retardation members 72B so as to straddle therebetween. That is to say, the two microwave retardation members 72B adjacent to each other are arranged on both sides of one tuner part 63B so as to extend in the circumferential direction from the position vertically overlapping with one tuner part 63B. Since the partition portion 11e is disposed immediately below the tuner part 63B as described above, the microwave electric power transmitted through the tuner part 63B is divided by the partition portion 11e and is evenly distributed to the microwave retardation members 72B existing on both sides of the tuner part 63B. Therefore, the microwave electric power is evenly distributed to the microwave retardation members 72B existing on both sides of the tuner part 63B without increasing the electric field intensity in the region immediately below the tuner part 63B, in which a microwave electric field normally tends to become large. Thus, the electric field intensity in the circumferential direction is brought into uniformity.

The microwave transmitting member 73B is made of a dielectric material which transmits microwaves. As shown in FIG. 6, the microwave transmitting member 73B has an annular shape as a whole. With such a shape, the microwaves transmitted through the three tuner parts 63B are radiated into the process container 2 through one common microwave transmitting member 73B to form uniform surface wave plasma in the circumferential direction.

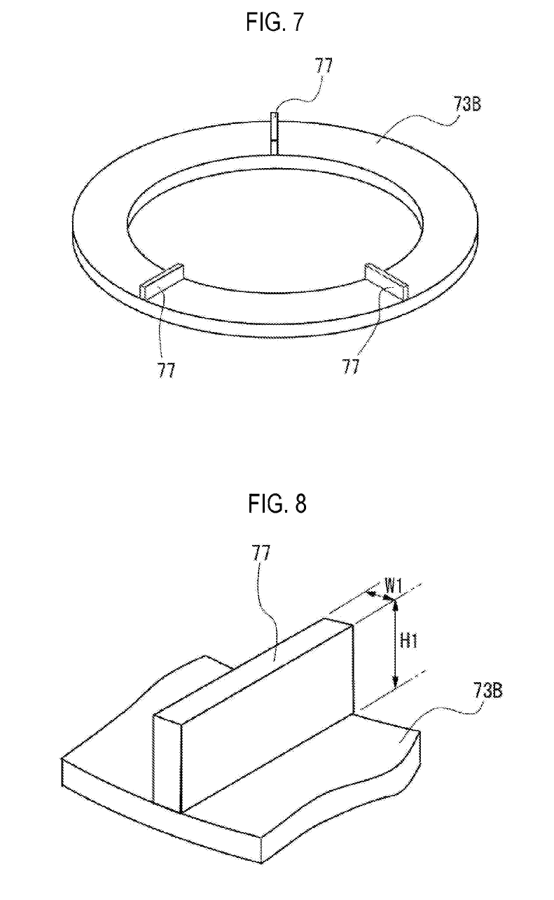

FIG. 7 is a perspective view showing an external appearance of the microwave transmitting member 73B used in the present embodiment. FIG. 8 is an enlarged perspective view of a main part of the wall portions 77 of the microwave transmitting member 73B. The wall portions 77 function as an interference suppressing means for suppressing interference of microwaves in the microwave transmitting member 73B. As shown in FIG. 7, the microwave transmitting member 73B has a plate-like shape and, as a whole, forms an annular shape in a plane view. In the microwave transmitting member 73B having such a shape, the wall portions 77 are equally arranged at three locations as protrusions protruding upward from the upper surface of the microwave transmitting member 73B. As shown in FIG. 5, the three wall portions 77 are equally arranged with an angle of 120 degrees in the circumferential direction at the locations not vertically overlapping with the tuner parts 63B. Each of the wall portions 77 has a quadrangular columnar shape processed integrally with the microwave transmitting member 73B. That is to say, each of the wall portions 77 has one upper surface and four side surfaces. The upper surface and the side surfaces are rectangular in shape. The respective side surfaces extend vertically upward from the upper planar surface of the plate-like microwave transmitting member 73B, thereby forming a quadrangular columnar protrusion. On the upper surface of the annular microwave transmitting member 73B, the wall portions 77 extend in the radial direction so as to traverse the annular portion. That is to say, the longitudinal direction of the wall portions 77 coincides with the radial direction of the microwave transmitting member 73B.

The wall portions 77 have a function of canceling the microwaves propagating in the circumferential direction inside the microwave transmitting member 73B by reflected waves, thereby suppressing the interference of microwaves inside the microwave transmitting member 73B. That is to say, in the plasma processing apparatus 1 according to the present embodiment, the three microwaves transmitted via the three tuner parts 63B installed in the upper portion of the peripheral region of the ceiling portion 11 are respectively introduced into one common microwave transmitting member 73B via the microwave retardation members 72B and the slot antenna portion 74B. For example, when a microwave transmitting member not provided with the wall portions 77 is used, if the phases of the three microwaves are shifted from each other, an unpredictable interference between the microwaves may occur inside the microwave transmitting member, so that an electric field distribution may become uneven. Thus, there is a concern that a bias in the circumferential plasma distribution may occur in the process container 2. In order to prevent such a problem, in the present embodiment, the wall portions 77 of the microwave transmitting member 73B serve as stub tuners. The wall portions 77 generate reflected waves which cancel a part of the microwaves propagating in the circumferential direction inside the microwave transmitting member 73B and suppress the interference of the microwaves inside the microwave transmitting member 73B. In other words, the wall portions 77 suppress the interference of the microwaves by circumferentially dividing the microwave transmitting member 73B, which is integrally processed in an annular shape, from the viewpoint of microwave propagation. Therefore, by providing the wall portions 77, it is possible to homogenize the circumferential plasma distribution in the process container 2, so that uniformity of processing in the plane of the wafer W can be achieved.

As shown in FIGS. 7 and 8, the wall portions 77 are provided so as to extend across the entirety of the width direction of the annular portion of the microwave transmitting member 73B, which has a plate-like shape and which forms an annular plane-view shape as a whole (namely, the radial direction of the microwave transmitting member 73B). The height H1 and the thickness W1 of the wall portions 77 may be set in consideration of the relationship with the effective wavelength λ of the microwaves inside the microwave transmitting member 73B so as to effectively suppress the microwave interference inside the microwave transmitting member 73B and may be represented by the following equation:

H≈(λ/4)×f(W1),

where f(W1) denotes a function of W1.

The shape, the height H1 and the thickness W1 of the wall portions 77 are not limited to the above embodiment. In addition, the number of the wall portions 77 to be disposed is not limited to three and may be set depending on the number of microwave transmission paths.

The slot antenna portion 74B is a constituent part of the ceiling portion 11, which is a conductive member, and has a flat plate shape. The slot antenna portion 74B mode-converts the microwaves transmitted from the tuner parts 63B as TEM waves into TE waves by slots 75b and radiates the microwaves into the process container 2 via the microwave transmitting member 73B.

As shown in FIG. 4, the slots 75b are formed as holes which extend through the ceiling portion 11 from the upper surface position making contact with the microwave retardation member 72B to the lower surface position making contact with the dielectric layer 76. The slots 75b determine the radiation characteristics of the microwaves transmitted from the tuner parts 63B. The periphery of each of the slots 75b is sealed by a seal member (not shown). As a result, the microwave transmitting member 73B covers and closes the slots 75b and functions as a vacuum seal. The antenna directivity is determined by the shape and arrangement of the slots 75b. The slots 75b have an arcuate shape. In order to evenly distribute the electric field, the slots 75b are provided along the arrangement regions of the tuner parts 63B such that the entire shape thereof becomes a circumferential shape. As shown in FIG. 5, in the present embodiment, twelve arcuate slots 75b are arranged in a line in the circumferential direction along the arrangement regions of the tuner parts 63B.

Furthermore, two slots 75b are provided for each microwave retardation member 72B. The circumferential length of one slot 75b is preferably λ2. λ is the effective wavelength of the microwaves and may be represented by the following equation:

λ≈(λ₀εₛ^{1/2})/{1−[(λ₀/εₛ^{1/2})/λ_{c}]²}^{1/2},

where εₛ denotes the relative permittivity of a dielectric material filled in the slots 75b, λ₀ denotes the wavelength of microwaves in vacuum, and λ_{c} denotes the cutoff frequency.

As shown in FIG. 4, a plurality of dielectric layers 76 is provided in a corresponding relationship with each of the slots 75b. In this example, twelve dielectric layers 76 are provided in a corresponding relationship with the twelve slots 75b. The dielectric layers 76 adjoining each other are separated by the metal-made ceiling portion 11. In each of the dielectric layers 76, a magnetic field of a single loop can be formed by the microwaves radiated from the corresponding slot 75b, so that the coupling of a magnetic field loop does not occur in the microwave transmitting member 73B disposed under the dielectric layers 76. Thus, it is possible to prevent the advent of a plurality of surface wave modes, thereby realizing a single surface wave mode. From the viewpoint of preventing the advent of a plurality of surface wave modes, it is preferred that the circumferential length of each of the dielectric layers 76 is not more than λ/2, where λ is the effective wavelength of the microwaves in each of the dielectric layers 76. In addition, the thickness of each of the dielectric layers 76 is preferably 1 to 5 mm.

Each of the dielectric layers 76 may be air (vacuum) or may be a dielectric material such as dielectric ceramics or resin. As the dielectric material, it may be possible to use, for example, quartz, ceramics, a fluorine-based resin such as polytetrafluoroethylene or the like, and a polyimide-based resin. In the case where the plasma processing apparatus 1 using a 300 mm wafer W to be process, the wavelength of the microwaves of 860 MHz, the microwave retardation member 72B, the microwave transmitting member 73B and alumina having a dielectric constant of about 10 used as the dielectric material in the slots 75b, it may be possible to use an air layer (vacuum layer) as each of the dielectric layers 76.

In this way, in the present embodiment, the dielectric layers 76 are provided in a mutually-separated state under the slots 75b so as to correspond to the respective slots 75b. As a result, a single loop magnetic field can be generated in each of the dielectric layers 76 by the microwaves radiated from each of the slots 75b, whereby a magnetic field loop corresponding to each of the dielectric layers 76 is formed in the microwave transmitting member 73B. It is therefore possible to prevent the occurrence of a magnetic field coupling in the microwave transmitting member 73B. Thus, it is possible to prevent the advent of a plurality of surface wave modes due to the occurrence or non-occurrence of a magnetic field loop in the microwave transmitting member 73B. This makes it possible to realize stable plasma processing free from mode jump.

The interior of the slots 75a and 75b of the slot antenna portions 74A and 74B may be kept in a vacuum. However, it is preferred that the interior of the slots 75a and 75b are filled with a dielectric material. By filling the slots 75a and 75b with the dielectric material, the effective wavelength of the microwaves becomes shorter and the thickness of the slots 75a and 75b can be made small. As the dielectric material filled in the slots 75a and 75b, it may be possible to use, for example, quartz, ceramics, a fluorine-based resin such as polytetrafluoroethylene or the like, and a polyimide-based resin.

In addition, the microwave retardation members 72A and 72B, which have a dielectric constant larger than that of a vacuum, may be composed of, for example, quartz, ceramics such as alumina or the like, or a synthetic resin such as a fluorine-based resin, a polyimide-based resin or the like. Since the wavelength of the microwaves becomes longer in a vacuum, the microwave retardation members 72A and 72B have a function of shortening the wavelength of the microwaves, which results in reducing the size of the antenna. The phase of the microwaves varies depending on the thickness of the microwave retardation members 72A and 72B. Thus, by adjusting the phase of the microwave depending on the thickness of the microwave retardation members 72A and 72B, it is possible to adjust the slots 75a and 75b to be positioned at antinodes of standing waves. As a result, it is possible to suppress generation of reflected waves in the slot antenna portions 74A and 74B and to increase the radiant energy of the microwaves radiated from the slots 75a and 75b. That is to say, the power of the microwaves can be efficiently introduced into the process container 2.

Similar to the microwave retardation members 72A and 72B, the microwave transmitting members 73A and 73B may be composed of, for example, quartz, ceramics such as alumina or the like, or a synthetic resin such as a fluorine-based resin, a polyimide-based resin or the like.

With the microwave introduction parts 6A and 6B configured as described above, the microwaves transmitted via the tuner parts 63A and 63B reach the slot antenna portions 74A and 74B. And then, the microwaves are radiated into the internal space of the process container 2 from the slots 75a and 75b of the slot antenna portions 74A and 74B through the microwave transmitting members 73A and 73B. At this time, in the peripheral region of the ceiling portion 11, the microwaves are radiated from the slots 75b, which are formed to have an annular shape as a whole. The microwave transmitting member 73B is provided in an annular shape so as to cover the slots 75b. Thus, the microwave power uniformly distributed by the microwave retardation member 72B as described above can be evenly radiated from the respective slots 75b and can be circumferentially spread by the microwave transmitting member 73B. Therefore, since it is possible to annularly form a uniform microwave electric field immediately below the microwave transmitting member 73B, uniform surface wave plasma can be formed in the circumferential direction in the process container 2.

### <Procedure of Plasma Processing>

The plasma processing using the plasma processing apparatus 1 may be performed, for example, by the following procedure. First, for example, a command is inputted from the user interface 82 to the process controller 81 so as to perform plasma processing in the plasma processing apparatus 1. Then, in response to the command, the process controller 81 reads the recipe stored in the memory part 83 or the computer-readable storage medium. Next, control signals are sent to the respective end devices of the plasma processing apparatus 1 (for example, the high-frequency bias power supply 25, the gas supply device 3a, the exhaust device 4, the microwave introduction device 5, etc.) so that plasma processing can be performed according to the conditions based on the recipe.

Next, the gate valve G is brought into an open state and the wafer W is loaded into the process container 2 through the gate valve G and the loading/unloading gate 12a by a transfer device (not shown). The wafer W is mounted on the mounting surface 21a of the mounting table 21. Then, the gate valve G is brought into a closed state and the interior of the process container 2 is depressurized and exhausted by the exhaust device 4. Subsequently, the rare gas and the process gas are introduced into the process container 2 at predetermined flow rates via the gas introduction part 15 by the gas supply mechanism 3. The internal pressure of the process container 2 is adjusted to a predetermined pressure by adjusting the exhaust amount and the gas supply amount.

Next, the microwave output part 50 generates microwaves to be introduced into the process container 2. The plurality of microwaves outputted from the distributor 54 of the microwave output part 50 is inputted to the plurality of antenna modules 61 of the microwave transmission part 60. At this time, in response to the control signal transmitted from the control part 8, in the antenna modules 61 respectively connected to the three tuner parts 63B arranged in the upper portion of the peripheral region of the ceiling portion 11, the phases of the microwaves transmitted from the respective antenna modules 61 are controlled by the phase shifter 62A to be matched with each other. However, a shift in phase may occur between the three microwaves transmitted via the three tuner parts 63B provided in the upper portion of the peripheral region of the ceiling portion 11 with respect to one common microwave transmitting member 73B. In order to avoid the bias of an electric field distribution attributable to such a phase shift and an influence by plasma, in the present embodiment, the wall portions 77 are provided in the microwave transmitting member 73B in one embodiment. The interference of the microwaves in the microwave transmitting member 73B can be suppressed by the wall portions 77.

In each of the antenna modules 61, the microwaves propagate through the amplifier part 62 and the tuner parts 63A and 63B and reach the microwave introduction parts 6A and 6B. Then, the microwaves penetrate the microwave transmitting members 73A and 73B from the slots 75a and 75b of the slot antenna portions 74A and 74B and are radiated into the space existing above the wafer W in the process container 2. In this manner, the microwaves are separately introduced into the process container 2 from each of the antenna modules 61.

As described above, the microwaves introduced into the process container 2 from a plurality of regions respectively form electromagnetic fields in the process container 2. As a result, the rare gas or the process gas introduced into the process container 2 is turned into plasma. Thus, a film forming process or an etching process is performed on the wafer W by the action of active species, for example, radicals or ions, existing in the plasma.

When a control signal for terminating the plasma processing is sent from the process controller 81 to the respective end devices of the plasma processing apparatus 1, the generation of the microwaves is stopped and the supply of the rare gas and the process gas is stopped. Thus, the plasma processing with respect to the wafer W is terminated. Next, the gate valve G is brought into an open state and the wafer W is unloaded by a transfer device (not shown).

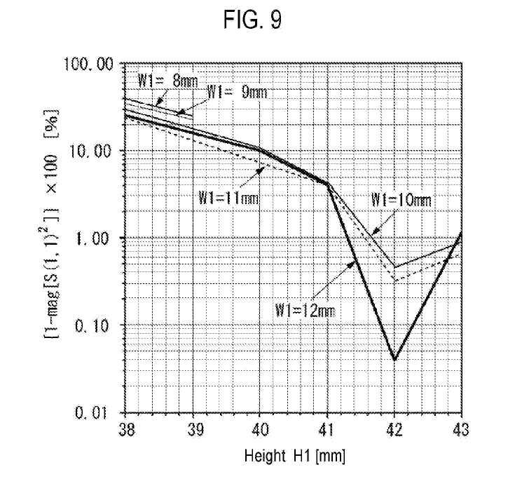

Next, the simulation results confirming the effect of the present disclosure will be described with reference to FIG. 9. In a simulation, investigation was conducted as to how much the microwave power of 100 W introduced through one tuner part 63B among the three tuner parts 63B arranged in the upper portion of the peripheral region of the ceiling portion 11 propagates to other adjoining tuner parts 63B arranged at intervals of 120 degrees in the circumferential direction. FIG. 9 shows the results obtained when the thickness W1 of the wall portion 77 in the microwave transmitting member 73B is changed from 8 mm to 12 mm by 1 mm and the height H1 of the wall portion 77 is changed from 38 mm to 43 mm. The vertical axis in FIG. 9 indicates the ratio (%) of the amount of electric power detected in the adjoining tuner parts 63B to the total amount of electric power in the tuner part 63B into which the microwave power is introduced. The horizontal axis indicates the height H1 of the wall portion 77.

It was confirmed from FIG. 9 that the microwave power propagating to the adjoining tuner parts 63B can be effectively suppressed by providing the wall portion 77 interposed between the two tuner parts 63B and appropriately setting the height H1 and the thickness W1 of the wall portion 77. In this simulation, when the thickness W1 of the wall portion 77 is 12 mm and the height H1 of the wall portion 77 is 42 mm, the microwave power propagating to the adjoining tuner parts 63 B was most effectively suppressed.

According to the present disclosure, in the plasma processing apparatus 1 for introducing a plurality of microwaves into the process container 2 via one common microwave transmitting member 73B, it is possible to effectively suppress the interference of microwaves in the microwave transmitting member 73B. It is therefore possible to secure the uniform spreading of plasma so that the processing uniformity of the wafer W can be secured.

It should be noted that the present disclosure is not limited to the above-described embodiment and may be diversely modified. For example, in the above-described embodiment, the semiconductor wafer is used as the workpiece. However, the present disclosure is not limited thereto. For example, other substrates such as an FPD (flat panel display) substrate represented as a substrate for a liquid crystal display, a ceramic substrate, and the like may be used as the workpiece.

In the above-described embodiment, the microwave introduction part 6A is provided in the central region of the ceiling portion 11. However, the microwave introduction part may not be provided in the central region of the ceiling portion 11.

In addition, the configurations of the microwave output part 50 and the microwave transmission part 60 and the like are not limited to the above-described embodiment.

According to the present disclosure in some embodiments, in a plasma processing apparatus and a plasma processing method for introducing microwaves into a process container via one common microwave transmitting member, it is possible to effectively suppress interference of the microwaves in the microwave transmitting member. Accordingly, it is possible to secure the uniform spreading of plasma so that the processing uniformity of a workpiece can be secured.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a process container configured to accommodate a workpiece;
a mounting table disposed inside the process container and provided with a mounting surface configured to support the workpiece;
a microwave output part configured to generate microwaves and to distribute and output the microwaves to a plurality of paths;
a microwave transmission part configured to transmit the microwaves outputted from the microwave output part into the process container via a plurality of transmission paths; and
a microwave introduction part configured to radiate the microwaves transmitted by the microwave transmission part inside the process container,
wherein the microwave transmission part includes tuner parts disposed in the respective transmission paths and configured to match impedance between the microwave output part and an interior of the process container,
wherein the microwave introduction part includes:
a conductive member constituting a ceiling portion of the process container and having a recess formed to face the mounting surface;
a plurality of slots forming a part of the conductive member and configured to radiate the microwaves transmitted via the microwave transmission part; and
a microwave transmitting member fitted to the recess of the conductive member and configured to transmit and introduce the microwaves radiated from the plurality of slots into the process container, and
wherein the microwave transmitting member is provided to be shared with the microwaves transmitted via the transmission paths and includes an interference suppressing part configured to suppress interference of the microwaves in the microwave transmitting member.

2. The apparatus of claim 1, wherein the interference suppressing part is a protrusion formed in the microwave transmitting member having a plate-like shape.

3. The apparatus of claim 2, wherein the microwave transmitting member has an annular shape as a whole, and the protrusion is a wall portion provided on an upper surface of the microwave transmitting member across the microwave transmitting member in a radial direction.

4. The apparatus of claim 2, wherein the microwave introduction part further includes a plurality of microwave retardation members made of a dielectric material, and
the microwave retardation members are disposed above the plurality of slots of the conductive member in an annular shape as a whole along an annular region including a region vertically overlapping with arrangement regions of the tuner parts.

5. The apparatus of claim 4, wherein the protrusion is inserted between two adjacent microwave retardation members in a region not vertically overlapping with the arrangement regions of the tuner parts.

6. The apparatus of claim 1, wherein dielectric layers are separately provided between the plurality of slots and the microwave transmitting member in a corresponding relationship with the plurality of slots.

7. The apparatus of claim 6, wherein the dielectric layers are air layers or dielectric material layers.

8. A plasma processing method for processing a workpiece using the plasma processing apparatus of claim 1.
